(19) United States
(12) Patent Application Publication
(10) Pub. No.: US 2026/0133573 A1
(43) Pub. Date: May 14, 2026

(54) METHOD OF DISPLAYING DATA PERTAINING TO A ROTARY ELECTRIC MACHINE

(71) Applicant: VIBROSYSTM INC., Longueuil (CA)

(72) Inventors: Mathieu CLOUTIER, Longueuil (CA); Vincent LECOMTE, Longueuil (CA)

(21) Appl. No.: 19/380,542

(22) Filed: Nov. 5, 2025

Related U.S. Application Data
(60) Provisional application No. 63/754,012, filed on Feb. 5, 2025.
(60) Provisional application No. 63/720,229, filed on Nov. 14, 2024.

(51) Int. Cl. G05B 23/02; G01R 31/34

(52) U.S. Cl. CPC G05B 23/0272; G01R 31/343; G05B 23/0216

(57) ABSTRACT

The method can include displaying a plurality of graphs disposed parallel to one another, each graph extending linearly from a first end to a second end along a temporal axis spanning incremental values of time, and representing a sequence of severity levels of a corresponding one of the parameters encoded as different colors or tones over the incremental values of time, the incremental values of time being common to each one of the plurality of graphs such that severity levels aligned transversally to the temporal axes correspond to simultaneous moments in time. The dashboard so made available can help convert complex analyses into key performance indicators, and/or to identify regions of interest in large databases.

### FIELD

Embodiments described herein relate to method of displaying data acquired from sensors coupled to large, e.g., megawatt-range, rotary electrical machines.

### BACKGROUND

Large, e.g., MW-range, rotary electric machines, such as electrical hydro-generators, thermal generators used for producing electricity, or electrical mills in the mining industry, can be considered “critical” in the sense that eventual downtime can be highly undesirable and associated to significant costs and/or other severe inconveniences. The management of such critical assets is typically associated with certain considerations such as a motivation to avoid failures, limit downtime, and protection against physical intrusions and digital piracy.

### SUMMARY

One approach to address such issues involves monitoring of the “health” of the large rotary electric machines which can be done in a context of diagnosing conditions which are prone to leading to failures before such failures occur, and devising an intervention plan in an effort to alleviate or avoid the potential consequences associated to failure.

On one hand, the monitoring of the large rotary electric machines involves acquiring data, typically for various parameters, using sensors. Ultimately, specially trained, professional human workers referred to as analysts are in charge of performing such diagnoses and may further assist in devising intervention plans or raising alarms. There are various practical considerations involved not only in the acquisition of data from the large rotary electric machines, and in the training of the analysts, but also in terms of processing and communicating the data to the analysts. Indeed, the working time of the analysts represent a cost to the large rotary electric machine operators, and health monitoring is an interesting avenue for operators only to the extent where the analysis costs does not become dissuasive. It will be understood that overwhelming an analyst with raw data can quickly lead to a situation where the analysis time increases and the costs become dissuasive. Similarly, it can be preferred to avoid analyst displacements, which can involve communicating data over telecommunication networks, but this may come with a certain risk associated with digital piracy. To avoid such issues, many software tools can be deployed between the sensors which generate the data pertaining to the large rotary electric machine, and the analyst, such as software tools to provide safe telecommunication, and software tools to facilitate the interpretation of the data by the analyst and reduce analysis time.

For instance, amplitude values of individual parameters can be mapped to deviation severity levels using software tools, and the deviation severity levels can be communicated to the analyst instead of the amplitude values themselves. The severity levels can be representative of different levels of risk associated to the operation of the large rotary electric machine. For instance, different severity levels can be representative not only of different extents by which corresponding amplitude values deviate from values which are considered “normal”, but further of significant differences in the level of risk, and the extent to which a deviation from normal is associated to risk can differ from one parameter to another. Using such software tools, the task of associating amplitude values to deviation severity levels can be automated, rather than being performed by the analyst, which can save time to the analyst. The analyst can then simply consult the deviation severity level of a given parameter to obtain a first indication and may decide to look more deeply into the amplitude values only if the analyst’s interpretation raises an issue which appears to warrant further investigation.

While such software tools can undoubtedly be useful for the analyst, there remains several challenges for the analyst. Indeed, in some cases, the severity level associated to a given parameter may not be alarming (i.e., deemed to warrant further investigation) in and of itself, but may become alarming when taken into combination with other variations in severity level, such as variations in severity level of a same parameter at different moments in time, or, perhaps more difficultly, variations in severity levels of other parameters at a same or different moment in time. Machine health indicators which are translated into such complexes of symptoms can be particularly challenging to diagnose by analysts, and analysts desiring to validate whether such machine health indicators are at play may often be sent on wild goose chases into the available data, representing significant analyst work time and associated costs.

It was found that at least in some embodiments, such challenges could be addressed by using a particular form of visual display for the analyst. More specifically, the temporal evolution of the severity levels of a number of different parameters of the machine, over a given period of time, can be represented by a number of corresponding linear (single-axis) graphs where the axis (length) of the graphs represent evolving temporal coordinates (time) and the severity level at corresponding moments in time can be mapped as different colors or tones along the axis. These graphs can be arranged parallel to one another in a manner for same temporal coordinates of different ones of the graphs to be aligned along an orientation transverse to the axis of the graphs. It was found that by using such a display, some relevant information can be made more easily accessible to the analysts, requiring less analyst work time. Namely, scenarios where changes in severity level simultaneously affect two or more of the parameters can be easily visually discerned in the form of transversally aligned changes in color or tone on the visual display.

In accordance with one aspect, there is provided a method of displaying data pertaining to a plurality of parameters of a rotary machine on a display screen using a computer, the method comprising : displaying a plurality of graphs disposed parallel to one another, each graph extending linearly from a first end to a second end along a temporal axis spanning incremental values of time, and representing a sequence of severity levels of a corresponding one of the parameters encoded as different colors or tones over the incremental values of time, the incremental values of time being common to each one of the plurality of graphs such that severity levels aligned transversally to the temporal axes correspond to simultaneous moments in time.

In accordance with another aspect, there is provided a dashboard presenting data pertaining to a plurality of parameters, the dashboard comprising a plurality of graphs, each graph representing a sequence of severity levels of a corresponding one of the parameters along a linear axis corresponding to varying values of said time, with different ones of the severity levels corresponding to different ranges of deviation of amplitude values of the corresponding parameter from normal operating conditions and different ones of the severity levels encoded as different colors or tones, the graphs disposed parallel to one another, wherein alignments, in an orientation transversal to the linear axes, of occurrences of variations in severity levels for more than one of said parameters are indicative of issues which affect more than one of the parameters simultaneously.

In accordance with another aspect, there is provided a method of displaying data pertaining to a plurality of parameters of a large rotary electric machine using a computer, the method comprising : obtaining time-series data for the plurality of parameters including amplitude values evolving over time; obtaining different ranges of said amplitude values corresponding to different severity levels, for the different parameters; associating the amplitude values to corresponding ones of the severity levels based on a comparison with the different ranges; and displaying a plurality of graphs, each graph representing a sequence of said severity levels of a corresponding one of the parameters along a linear axis corresponding to varying values of said time, with different ones of the severity levels being encoded as different colors or tones, the graphs disposed parallel to one another; wherein alignments, in an orientation transversal to the linear axes, of occurrences of increases in severity levels for more than one of said parameters are indicative of issues which affect more than one of the parameters of the rotary machine at the corresponding time.

Many further features and combinations thereof concerning the present improvements will appear to those skilled in the art following a reading of the instant disclosure.

### DESCRIPTION OF THE FIGURES

In the figures,

FIG. 1A is an elevation view of a first example of a large electric machine;

FIG. 1B is an elevation view of a second example of a large electric machine;

FIG. 2 is a schematic view of an example system including components of monitoring equipment associated to a large electric machine;

FIG. 3 is a schematic of an example flow of information between the sensors and a graphical user interface;

FIG. 4 is a flow chart representing a method of displaying data pertaining to a large rotary electric machine;

FIGS. 5A, 5B, and 5C are example formats for a dashboard for embodiment where the large rotary electric machine is a turbo generator, a hydro generator, and a gearless mill drive, respectively;

FIG. 6A and 6B are two examples of a same dashboard representing different timespans; and

FIG. 7 is a block diagram of an example computer.

### DETAILED DESCRIPTION

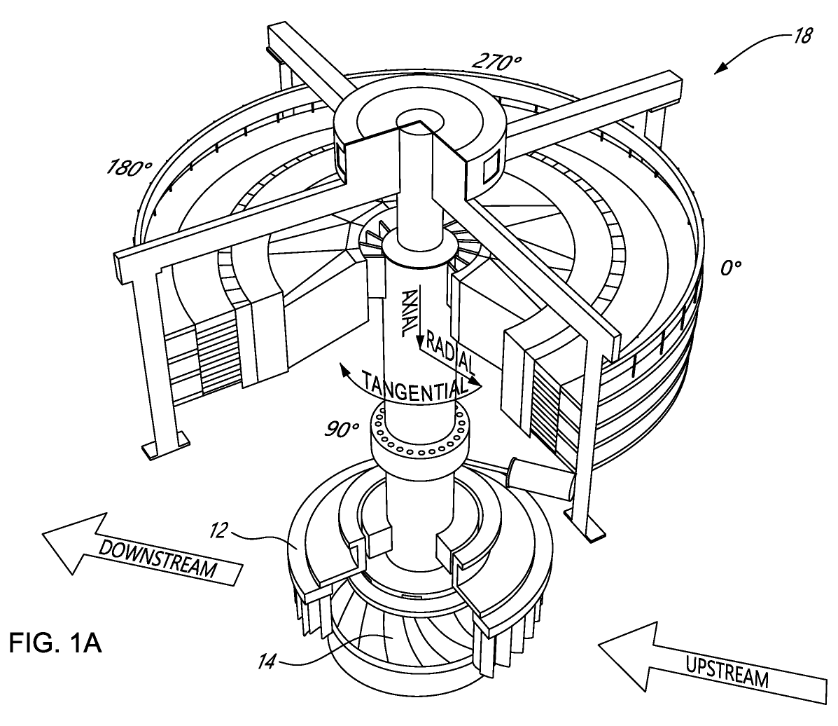

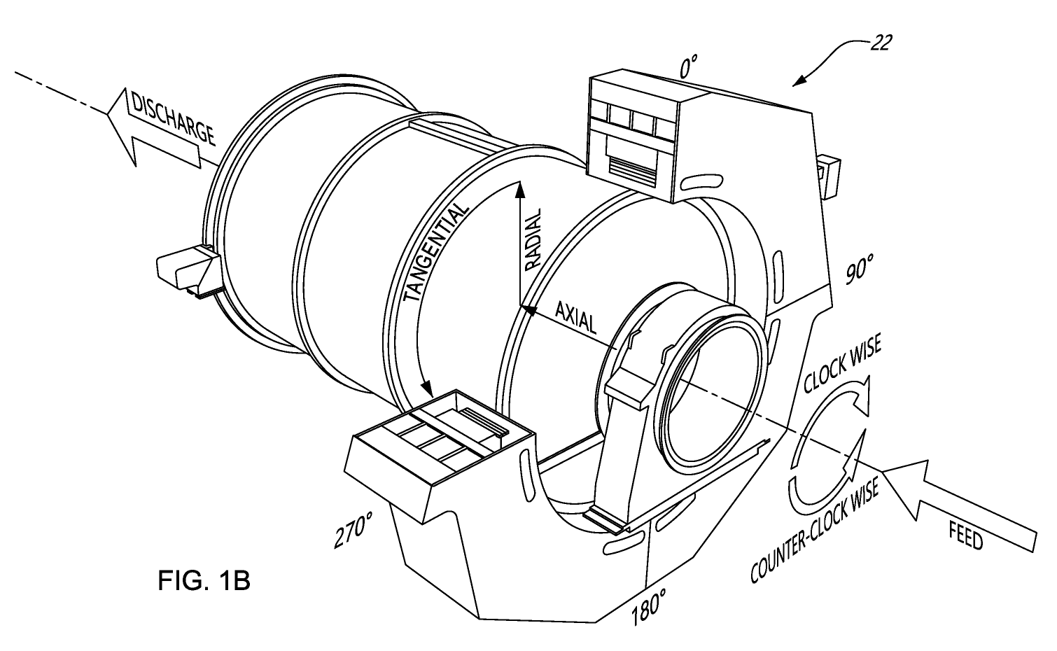

FIG. 1A shows an example of a large electric machine which, in this embodiment, is embodied as a generator. More specifically, the example electric machine is a Kaplan-type turbine 18. As depicted, the Kaplan-type turbine 18 has a stator 12 and a rotor 14 which is rotatably coupled to the stator and which rotation can be driven by an incoming flow of liquid along orientation D. Gas turbine generators and steam generators may also be embodied as large rotary electric machines.

FIG. 1B shows another example of a large electric machine embodied here as a Semi-Autogenous Grinding (SAG) mill 22. In this embodiment, the SAG mill has a rotor and a stator and is powered by electricity.

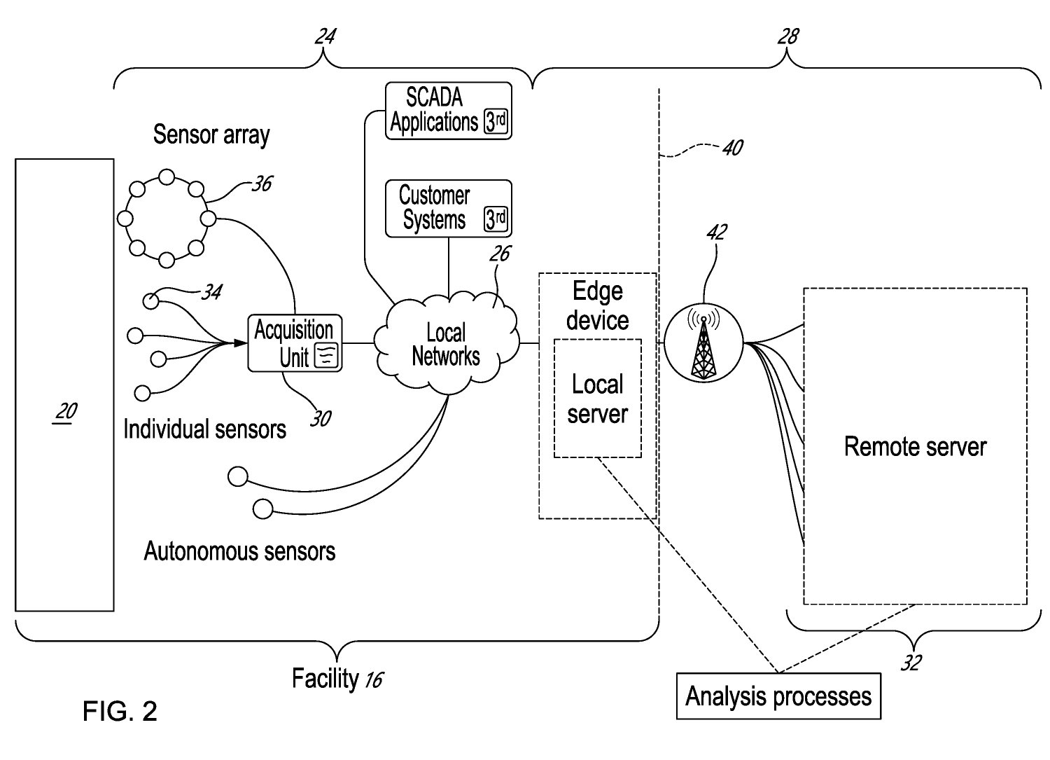

Both the Kaplan-type turbine 18 and the SAG mill 22 are examples of large electric machines. Referring to FIG. 2, large electric machines 20 are located at premises which may alternately be referred to as a facility 16 or industrial plant and are typically equipped with elaborated monitoring equipment. A given facility 16 can have one or more electric machine 20, and each electric machine 20 can have dedicated equipment while some of the monitoring equipment can be shared with more than one machine. The expression “large” here refers to the power range, and typically also implies a relatively large volume. The power range can be indicative of a criticality of the machine, in the sense that downtime for a machine having a greater power is typically more “costly” (e.g. in terms of lost profits or other inconveniences) than a smaller power machine, making the business case of investing to reduce the likelihood or duration of downtime often easier to make than on smaller electric machines. A given large rotary electric machine 20 can be in the range of hundreds of kilowatts (KW), in the range of megawatts (MW), or greater, for instance, depending on the embodiment. The monitoring equipment and the electric machine(s) 20 can be local to the facility 16, such as local to an electrical power plant or a mining milling plant.

In the embodiment schematically presented in FIG. 2 the facility 16 has one or more electric machines 20 and monitoring equipment 24. The monitoring equipment 24 can include sensors, acquisitions units and higher-level applications running on computer resources such as SCADA applications and systems owned by the plant owner (customer systems), and one or more local network 26, all of which can operate on hardware located at the facility 16. The monitoring equipment can also include a local server, for instance where the acquired data can be stored. The one or more local networks 26 via which the local hardware communicates with one another can be of the “operational technology” (OT) type and can operate based on Industrial Internet of Things (IIOT) technology for instance. Other local networks can be present or absent, and connected to the acquisition unit or disconnected from the acquisition, such as an Information Technology (IT) network such as Ethernet for instance. Elements constituting the local network(s) can be wired, wireless, or hybrid.

In some other embodiments, rather than, or in addition to, being stored locally, the acquired data can be stored remotely, such as on a remote server 32. In some cases, the acquisition unit 30 may communicate directly with the remote server via a telecommunications network 42 such as the Internet, whereas in other embodiments, communications between the local network(s) 26 and the external telecommunications network 42 may be controlled by an edge device. In the latter case, the acquisition unit 30 may transmit the data to the edge device via the local network(s), and the edge device, in turn, can coordinate the transmission of the data to the remote server. As such, the edge device can be positioned at a boundary 40 between the local network 26 and the telecommunications network 42. In some cases, an acquisition unit 30 may be integrated to a sensor as opposed to being provided in the form of a distinct component.

The monitoring equipment 24 can include sensors configured to monitor the status (e.g. health) of the electric machine 20. Sensors can be provided in various forms, such as discrete sensors 34, sensor arrays 36, autonomous (e.g. wireless) sensors 38, etc. The sensors generate information indicative of the status of the electric machine 20.

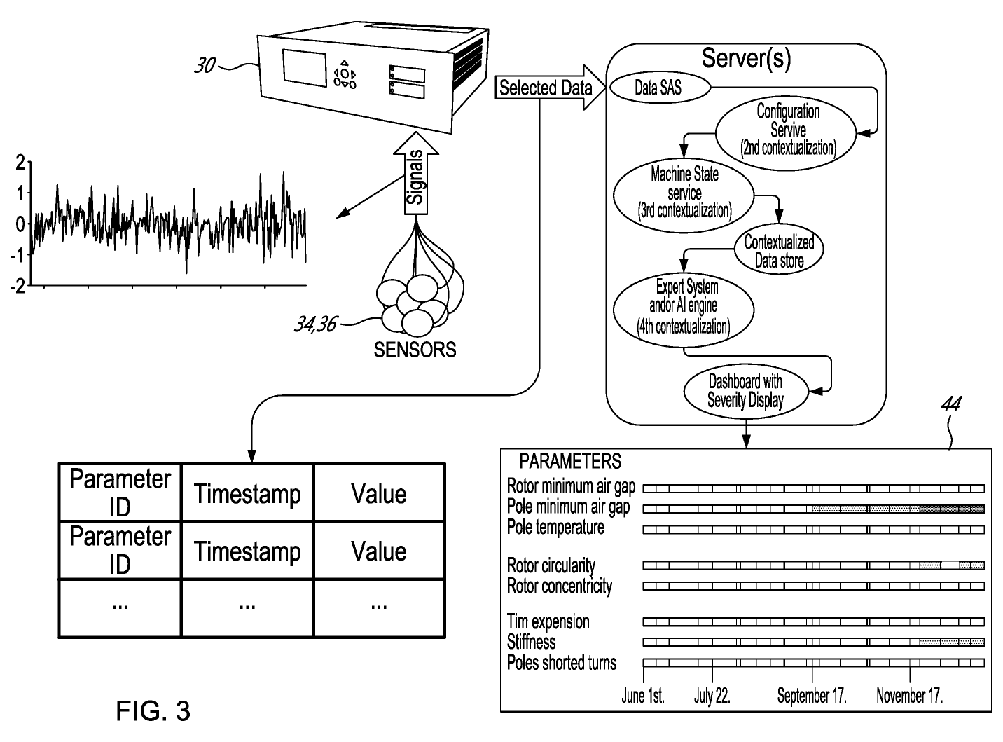

Independently of whether data pertaining to the electric machine is stored in a local server, a remote server, or both, the general information flow can be as exemplified in FIG. 3, where the sensors measure real-world physical conditions and generate signals (typically analog) representing time-varying values for different parameters associated with the large rotary electric machines. Acquisition units 30 are used to acquire data from the sensors 34, 36, which typically involves sampling the signals and converting the resulting samples into sequences of digital numeric values (sampled values) that can be manipulated by a computer. The resulting data can be time-series data representing the evolution of the values of the different parameters over time. Some or all data may be stored in the acquisition unit 30, such as for processing values of lower-level parameters into values of higher-level parameters, or any other suitable reason. Some or all data may be outputted from the acquisition unit 30. The data outputted from the acquisition unit 30 can be time-series data and can be usable to perform an analysis of the health of the rotary electric machine. Based on this analysis, certain important decisions may be taken, such as scheduling maintenance at a later time, or even voluntarily taking the penalty of interrupting the operation of the rotary electric machine to avoid the possible greater inconvenience of a potential failure.

In any case, performing an analysis of the data typically involves the work of a professional human referred to in the field as an analyst. The work of the analyst may be facilitated by using software tools. Various forms of software tools may be used, such as user interface technologies to facilitate the display, search, or interaction with the data, and alerts which can direct the analyst’s attention to data associated to segments of time when the rotary electric machine was operating outside expected operating conditions.

Data needs to be contextualized in order to be of use in an analysis, independently of whether the analysis is performed by a human analyst or whether processing is performed by a software tool. Indeed, a number of values, without any means of determining what these values represent or when they were acquired, is useless. Referring to the example presented in FIG. 3, there can be different layers of contextualization, and some contextualization can even be performed by the acquisition unit 30 itself, such as by appending to each one of the values it outputs an identifier (ID) of the parameter which it pertains to, and a timestamp which can correspond to the time indicated by an internal clock at the time of acquisition. The identifier can be used to provide information as to what the value represents, whereas the timestamp can be used to provide information as to when the value was sampled.

One way of keeping track of what the values represent is, on the one hand, to keep a configuration file within a memory of the acquisition unit 30, indicating information such as what the different sensors are and where different sensors were mounted at the time of assembly, and on the other hand, to keep track of which sensor each data item originates from. This can allow the subsequent contextualization of where on the machine the data originates from and what physical measurements are indicated based on the information of which sensor the data item originates from and the information in the configuration file.

Indeed, each sensor can be said to measure real-world physical values pertaining to a given parameter associated with the large rotary electrical machine. Such parameters can be referred to herein as first-level parameters, since they relate to things which are directly measured by the sensors, and can be tracked more specifically by identifiers of the sensors, for instance. In some other cases, values of certain parameters can be computed based on two or more values of first-level parameters. Examples will be provided below. Such computed values can be said to pertain to higher-level parameters, or composite parameters, and can be tracked more specifically by identifiers of such higher-level parameters. Both sensor IDs and higher-level IDs can be said to constitute parameter IDs.

Example of data pertaining to higher-level parameters which can be computed based on lower-level data will now be provided. In a first example, higher-level data pertains to the minimum distance between the rotor poles and the stator, which can be referred to as the “minimum point per pole”. The data pertaining to the minimum point per pole can be useful during analysis for operations such as calculating and monitoring the shape of the rotor, calculating and monitoring the shape of the stator by using the minimum point of a pole measured by all sensors distributed on a stator (e.g., minimum 4 sensors), calculating the circularity and concentricity of the rotor and/or stator, monitoring the variation of the minimum point per pole for each pole for each turn, etc.

Let us take an example of a MW range hydroelectric generator which has 22 poles and where one revolution lasts 138.33 ms at nominal speed. At each revolution, each sensor may sample 1833 values over the 183.33 ms, whereas the minimum point for 1 revolution may correspond to 22 of these 1833 values per revolution. In addition to the sensors which measure the distances, this calculation can further be based on a synchronization sensor, sometimes referred to as “synchro”, which can have the purpose of determining the beginning and the end of each revolution of the machine. After the signal indicating the beginning of a turn of the machine is received a software function can detect the beginning of a pole based on the pole beginning threshold. The software function may then store, in the memory, the smallest value sampled by the sensor between the pole beginning threshold and a pole ending threshold. The beginning threshold and the ending threshold may be configurable. Once the pole ending threshold has been reached, the module can associate the smallest value to the pole ID and increment the pole ID. The pole ID can be reset to 1 based on the synchro signal. The result for each pole/sensor can be a limited collection of higher-level data values corresponding to the minimum points, which can be much more discrete than the (quasi-)continuous sampling of the values by the corresponding sensor. In some cases, the data pertaining to the continuous sampling may be deleted from memory once the minimum points have been computed, and only the minimum points may be passed on to the next steps of the data flow. When outputted, the minimum points per pole can be identified as minimum points for a given pole, as opposed to simply a value outputted by a given sensor coupled to the corresponding pole, and an identifier of this higher-level parameter can be defined and tagged.

A second example of calculating higher-level data based on lower-level data pertains to the displacement of the shaft of a large rotary electric machine. Indeed, when calculating circularity and concentricity of the stator and rotor, the S-vector, which indicates the direction of displacement of the shaft, is useful. The amplitude of the S vector at the centers of the poles can be particularly relevant. A software function can be provided to calculate the s vector on each sample of two sensors. These calculations can factor in the 1/pole compressed time series to calculate the amplitude of the s vector per pole. In the example case of a MW range hydroelectric generator which has 22 poles and where one revolution lasts 183.33 ms at nominal speed. At each revolution, the number of values of calculated S vector values, when performed at the sampling rate, can be of 1833 values over the 183.33 ms, whereas the S vector at 1 point/pole can bring this down to 22 of these 1833 values per revolution. The latter higher-level parameter can be computed based on the s vector time series in combination with the 1/pole time series. The software function may then store, in the memory, a single value of the s vector for each period of alignment with a pole, such as the value of the s vector for the position/time corresponding to the minimum distance.

A third example can involve signals generated by vibration sensors. In the data sampled from such sensors, certain elements may be more relevant for analysis than others, such as the fundamental frequency of the machine, the harmonic frequencies, and the sub-harmonic frequencies. A software function may be configured to transform the temporal signal into a frequential signal. Frequencies of interest can be extracted via frequency bands. The higher-level data extracted from the calculations may include only the frequency and amplitude of the highest amplitude point within a given frequency band, for example.

Alternately, parameters can take the form of phenomena identified in the data using trained engines (AI).

Typically, the data items outputted by the acquisition unit 30 and/or by the edge device will have a data format, an example of which is presented in FIG. 3. In this example, the data format of the data items includes the parameter ID and the timestamp in addition to the value and can include different streams of time series data corresponding to different parameters. The different fields of the data format can be in a different order in other applications, as long as the order is known at the time of analysis to allow us to make sense of the different fields. This can be referred to as first level contextualization.

It will be understood that if only first level contextualization was performed prior to making the data available for analysis by a human analyst, the human analyst can quickly become overwhelmed. Indeed, particularly in typical cases where the data include time series data for multiple parameters over lengthy periods of time for just a single machine, there can remain a significant burden of zoning in on data of relevance amongst the amount of available data. Additional levels of contextualization, which may alternately be referred to as automated processing tasks, can be provided to facilitate the analysis process.

For instance, some information pertaining to what will be referred to herein as a second level of contextualization can be collected at the time of assembly or of reconfiguration of the sensors, for instance. This information can be entered in a database and made available for a second level of contextualization by what will be referred to herein as a configuration service. Such information can include sensor information, such as sensor location, part monitored by a sensor, sensor output details, or information as to which sensor (sensor ID) is associated with which acquisition unit, which module, which channel, etc. Such information can further include information pertaining to the large rotary electrical machine to which the sensor is coupled, for instance, such as nominal speed, nominal air gap, number of poles, number of bars, dimensions, etc. Second-level contextualization may be performed on the data which has previously been outputted by the acquisition unit, such as in a server, whereas in certain cases, certain elements of higher-level contextualization may be provided by the acquisition itself. This being said, there is typically an inconvenience associated to requiring too much computing power or memory of the acquisition unit itself, which may make it more convenient in some cases for computer-intensive functions to be performed by a separate, more powerful computer, such as a local or remote server.

Moreover, some information pertaining to what will be referred to herein as a third level of contextualization may be calculated or otherwise inferred based on the data contextualized by the first and/or second levels of contextualization, and/or by additional data. Such information can include information pertaining to the state of operation of the rotary electrical machine, for instance, such as rotation speed (which may be computable from synchro or air gap sensor data for instance), temperature, magnetic field, etc.

Third level contextualization can be important for the purposes of simplifying or increasing the efficiency of analysis, be it an analysis performed by a professional human, or an analysis performed by automated means such as algorithms or trained engines (artificial intelligence).

In some embodiments, third level contextualization may be performed post-acquisition, e.g., at a local or remote server, based on automated functions implemented by execution of associated computer-implemented instructions, which may compute third level contextualization information based on the first and/or second levels of contextualization and on known relationships between these different elements of data.

Analysis may provide an even higher level of contextualization. For instance, algorithms may be adapted to classify phenomena identified in the data in terms of severity, or trained engines may be used to perform automated pattern recognition, which may detect, in the data, signatures which, when taken into consideration with machine state of operation, can allow to identify potentially abnormal changes.

As also shown in FIG. 3, it will also be noted that graphical user interface tools can also be provided to facilitate interpretation of data by a human, such as an analyst, machine owner, or machine operator. In the example presented in FIG. 3, time series data pertaining to severity levels, as opposed to measured values, can be produced as an output of 4^{th} level contextualization, and graphically displayed, as a dashboard 44 on a display screen of a computer, as timelines for different ones of a number of parameters of the large electrical rotary machine. In this manner, a human can easily visualize, at a glance, the evolution of assessed severity levels of many different, and in some cases relatively high-level, parameters over time, with a single glance at a computer display screen.

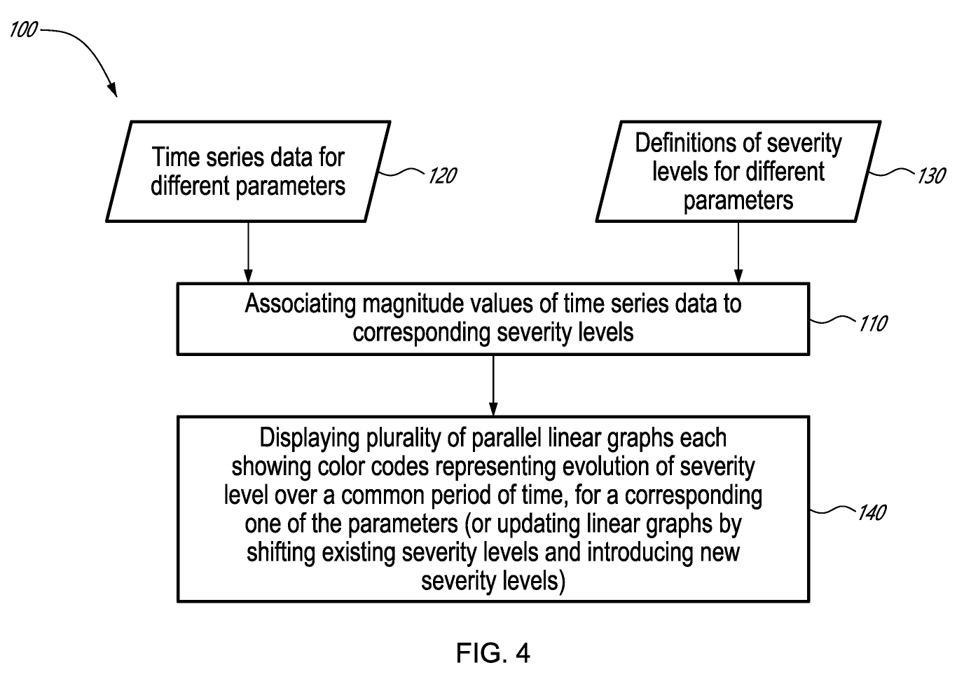

A dashboard 44 such as shown in FIG. 3 can be displayed on an electronic display screen using a computer, using a method 100 represented in FIG. 4. In one step 110 of the method, for instance, amplitude values in the time-series data for different parameters 120 can be mapped to deviation severity levels based on definitions of the severity levels 130 which can be stored in a memory of the computer. The severity levels can be representative of different levels of risk associated to the operation of the large rotary electric machine. For instance, different severity levels can be representative of different extents by which corresponding amplitude values deviate from values which are considered “normal”. The way the ranges corresponding to the different severity levels are defined for a given parameter can depend on considerations such as how likely it is for the amplitude values of the parameter to reach that range and/or what risks are considered to be associated with the reaching of that amplitude value for that parameter.

In a subsequent step 140, a dashboard 44 can be displayed on the electronic display screen. The dashboard 44 can include a plurality of linear graphs corresponding to different ones of the parameters. The linear graphs can be disposed parallel to one another. The linear graphs can each extend along a single axis encoding a common time span which can be in the order of weeks or months, or any other suitable range. The values of severity levels (e.g., normal, low, medium, high) can be color coded (e.g., green, yellow, orange, red). Accordingly, for each parameter, a number of severity levels corresponding to different times within the time span can be displayed by a corresponding portion being displayed in the corresponding color or tone, resulting in a continuous or discontinuous linear evolution of colors or tones mapped along the axis corresponding to temporal coordinates and representing the evolution of severity level of individual parameters over time.

The dashboard can further display human-readable identifiers representing the different parameters corresponding to the different graphs, and/or human-readable identifiers indicative of the period of time. Indeed, in the example illustrated in FIG. 3, the dashboard 44 not only includes the plurality of linear graphs, but a name of the corresponding parameter adjacent each one of the graphs, and date labels providing temporal reference to the human user. In the specific case of FIG. 3, the amplitude values of pole minimum air gap can instantly be seen to have transitioned from normal to low severity around September 17 and then transitioned from low severity to medium severity shortly after November 17, at which point rotor circularity and stiffness simultaneously transitioned from normal to low severity.

While making such interpretations now appears easy using the graphical representation afforded by the dashboard, one can imagine how difficult it could be to analysts to reach such conclusions, particularly when it comes to the realization that the worsening of the condition of pole minimum air gap is temporally tied to the worsening of the condition of the rotor circularity and stiffness, without this dashboard. Indeed, analysts which do not have access to such a dashboard can spend a lot of time scouring databases to identify zones of interest before even beginning to make a diagnostic. Moreover, it can be particularly challenging for analysts to make correlations between what happens at one part of the machine with what may be happening at other parts of the machine at a same moment in time, without such visual representation. The dashboard 44 can allow not only to rapidly identify zones of interest, but also quickly determine whether the situation has effects on other parts of the machine.

Various embodiments are possible. Indeed, for instance, the combination of parameters being monitored in a specific embodiment can depend not only on the particularities of the machine, but also on the specific combination of sensors which have been selected to monitor a specific machine, and on the specific combination of parameters which have been selected for display as part of the dashboard. Moreover, there can be many variations in the way the different severity levels are defined, and in the color or tone scales in which the different severity levels are encoded.

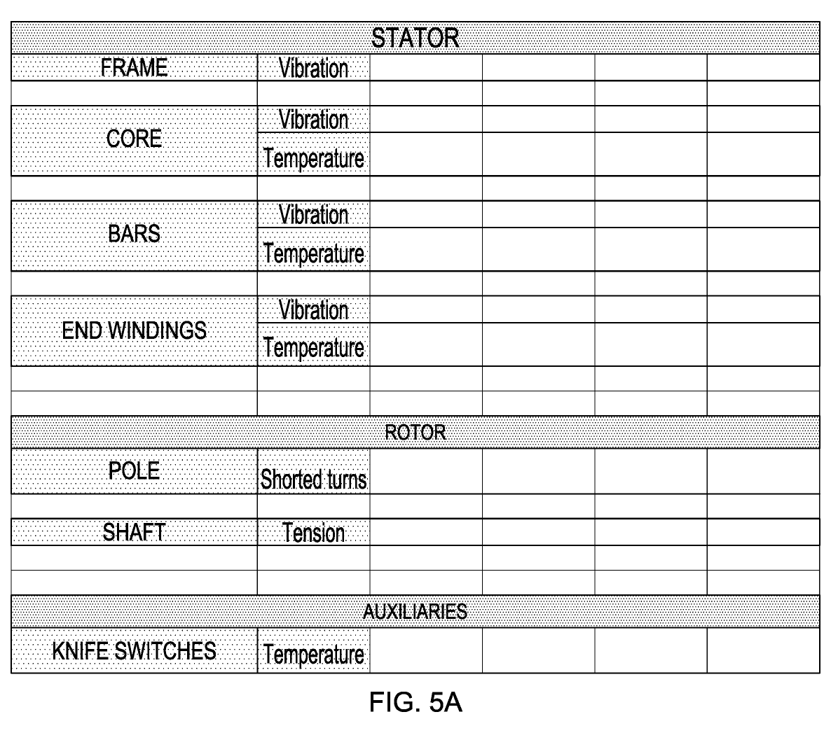

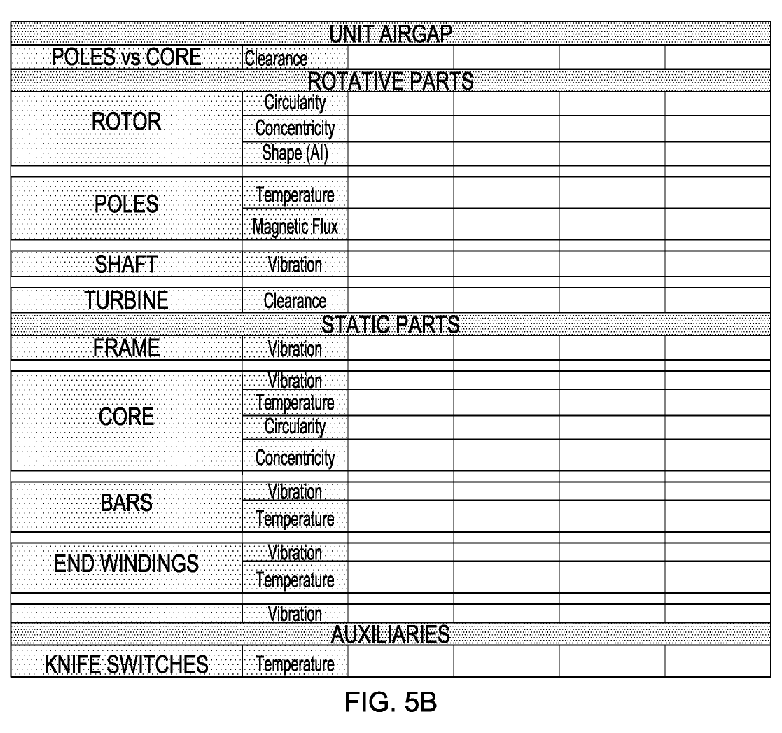

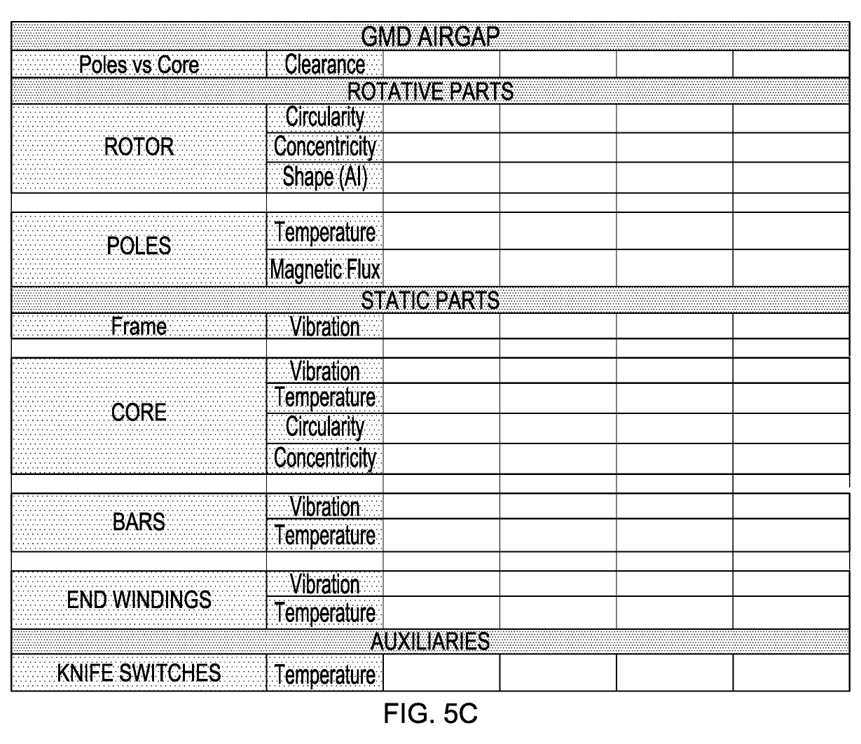

FIG. 5A presents an alternate example of a dashboard frame, i.e., a dashboard without the linear graphs/severity level representations, for an example turbo generator. In this example, in some cases, more than one different parameter is grouped under a same machine parts indicator. For instance, end winding vibration and end winding temperature are displayed as vibration and temperature within a group corresponding to end windings, and so forth for bars and core, and end windings, bars, core and frame are grouped under a heading which is used for a group of parts, which are stator parts in this case. The linear graphs for each one of the parameters may be displayed in the space disposed on the right-hand side of the labels “vibration” and “temperature”, for instance and temporal coordinates can evolve from left to right, or from right to left, and be linear, or non-linear (e.g., logarithmic), for instance.

FIG. 5B presents an alternate example of a dashboard frame being generally on the same format as the dashboard frame of FIG. 5A but being configured for displaying data pertaining to parameters of a hydro generator instead of a turbo generator, showing one alternate example.

FIG. 5C presents an alternate example of a dashboard frame being generally on the same format as the dashboard frame of FIG. 5A but being configured for displaying data pertaining to parameters of a gearless mill drive instead of a turbo generator, showing an other alternate example.

It will be noted that instances of a same type of rotary electric machine in different facilities, or even within a given facility, may be equipped with more or less sensors depending on the operator’s preference. For example, some instances of a given type of rotary electric machine may be equipped with sensors for poles and/or end-windings, whereas other instances of the same type of machine may not be equipped by such sensors. In some embodiments, it may be preferred to use a same dashboard “frame”, such as the ones presented in FIGS. 5A-5C, for all such instances and simply provide a visual indication of any row which is inactive, such as by being greyed out or simply empty when the corresponding sensor is missing, for instance.

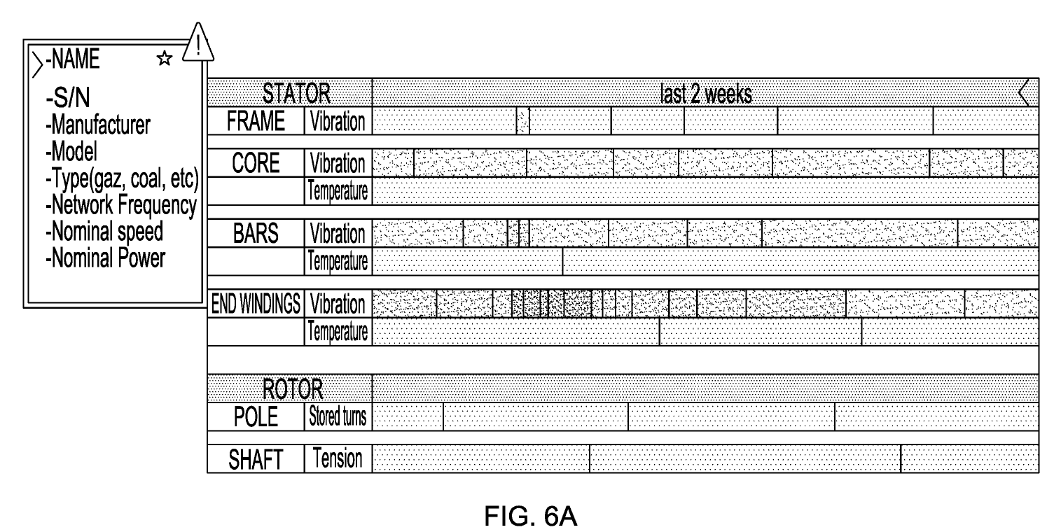

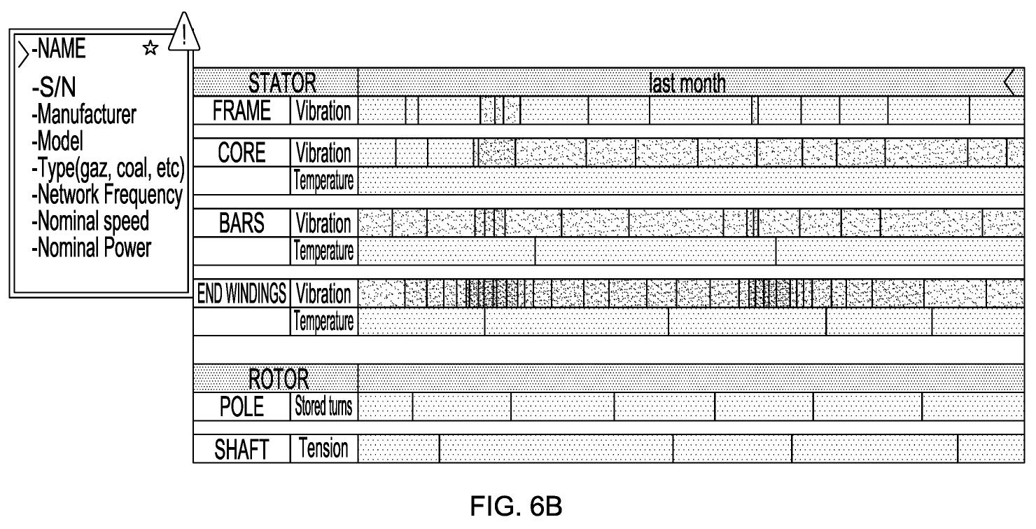

Depending on the embodiment, it may in some cases be deemed relevant to display more information than the dashboard itself on a given display screen, or to display more information on the dashboard. FIG. 6A and 6B present an additional example embodiment. In such an embodiment, the display may dynamically add a visual warning indicator, in this case a triangle icon with an exclamation mark, when severity levels above a given threshold are reached. Indeed, a visual or audible indicator may be executed by the computer when a “high severity” data element appears within the linear graphs, and may be sustained for a given duration, or for as long as a higher severity element remains displayed within any one of the linear graphs. In some cases, and particularly when several similar machines are being monitored by a same person, it can be relevant to provide more detail about the machine to which the data pertains. In the example presented in FIG. 6A and 6B, a panel can be displayed, for instance, with information pertaining to the corresponding machine, such as a name, serial number, manufacturer, model, type, network frequency, nominal speed and/or nominal power of the corresponding machine, or any other relevant information such as may originate from a unit configuration step. Such a panel may be displayed adjacent the dashboard, for instance. Moreover, still referring to the example presented in FIG. 6A and 6B, in some cases, the common time span, such as last 2 weeks, or last month, may be displayed in association with the dashboard. In some embodiments, a user interface may allow zooming into or out of a more specific time span. For instance, in one embodiment, a user may transition between showing the last two weeks and the last months by hovering a mouse cursor over the dashboard and turning a mouse wheel in one direction or another, or by interacting, via a mouse or touchscreen, with zoom in and zoom out buttons or a scroll bar provided as part of a graphical user interface, to name some examples. In yet another embodiment, the dashboard can be printed on paper.

In some embodiments where a dashboard is displayed on a graphical user interface of an electronic device such as a desktop computer, laptop computer, smart phone or tablet, it may be relevant in some cases to allow dynamically updating a given dashboard as new data becomes available. Such a dynamic update can involve shifting the severity level color codes forming each one of the linear graphs towards one end of the graphs, deleting one or more severity level color codes which would have exceeded the frame of the linear graph due to the shifting, and introducing one or more new severity level color codes, corresponding to the new data, in the areas freed by the shifting at the other end of the graphs.

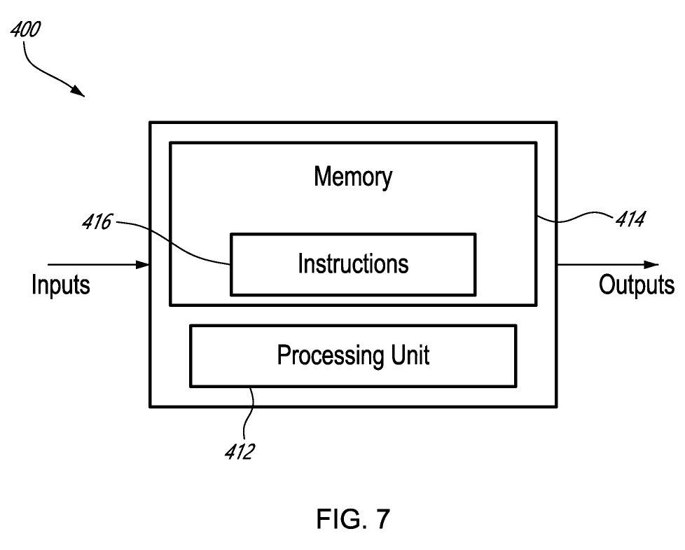

Referring to FIG. 7, it will be understood that the expression “computer” 400 as used herein is not to be interpreted in a limiting manner. It is rather used in a broad sense to generally refer to the combination of some form of one or more processing units 412 and some form of memory system 414 accessible by the processing unit(s). The memory system can be of the non-transitory type. The use of the expression “computer” in its singular form as used herein includes within its scope the combination of a two or more computers working collaboratively to perform a given function. Moreover, the expression “computer” as used herein includes within its scope the use of partial capabilities of a given processing unit.

A processing unit can be embodied in the form of a general-purpose micro-processor or microcontroller, a digital signal processing (DSP) processor, an integrated circuit, a field programmable gate array (FPGA), a reconfigurable processor, and a programmable read-only memory (PROM, to name a few examples.

The memory system can include a suitable combination of any suitable type of computer-readable memory located either internally, externally, and accessible by the processor in a wired or wireless manner, either directly or over a network such as the Internet. A computer-readable memory can be embodied in the form of random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM)to name a few examples.

A computer can have one or more input/output (I/O) interface to allow communication with a human user and/or with another computer via an associated input, output, or input/output device such as a keyboard, a mouse, a touchscreen, an antenna, a port, etc. Each I/O interface can enable the computer to communicate and/or exchange data with other components, to access and connect to network resources, to serve applications, and/or perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, Bluetooth, WiMAX), SS7 signaling network, fixed line, local area network, wide area network, to name a few examples.

It will be understood that a computer can perform functions or processes via hardware or a combination of both hardware and software. For example, hardware can include logic gates included as part of a silicon chip of a processor. Software (e.g. application, process) can be in the form of data such as computer-readable instructions stored in a non-transitory computer-readable memory accessible by one or more processing units. With respect to a computer or a processing unit, the expression “configured to” relates to the presence of hardware or a combination of hardware and software which is operable to perform the associated functions. Different elements of a computer, such as processor and/or memory, can be local, or in part or in whole remote and/or distributed and/or virtual.

As can be understood, the examples described above and illustrated are intended to be exemplary only. The scope is indicated by the appended claims.

What is claimed is:

1. A method of displaying data pertaining to different parameters of a large rotary electric machine using a computer, the method comprising:
obtaining time-series data for the different parameters including amplitude values evolving over time;
obtaining different ranges of said amplitude values corresponding to different severity levels, for the different parameters;
associating the amplitude values to corresponding ones of the severity levels based on a comparison with the different ranges; and
displaying a plurality of graphs, each graph representing a sequence of said severity levels of a corresponding one of the parameters along a linear axis corresponding to varying values of said time, with different ones of the severity levels being encoded as different colors or tones, the graphs disposed parallel to one another;
wherein alignments, in an orientation transversal to the linear axes, of occurrences of increases in severity levels for more than one of said parameters are indicative of issues which simultaneously affect more than one of the parameters of the rotary machine at the corresponding time.

2. The method of claim 1 further comprising dynamically updating the plurality of single-axis graphs by shifting said sequence of severity levels towards one end of the corresponding linear axes and introducing new severity levels corresponding to more recent amplitude values at another end of said linear graphs.

3. The method of claim 1 wherein said different severity levels correspond to increasing deviations from a range of said amplitude values corresponding to a normal severity level, and include at least one higher severity level, further comprising dynamically updating the display by introducing a warning icon when displaying said higher severity level in at least one of the linear graphs.

4. The method of claim 1 further comprising expanding or contracting a temporal scale of the linear graphs in response to receiving a user input indicative of a zooming in or zooming out command.

5. The method of claim 4 further comprising dynamically updating a human readable annotation indicative of the displayed period of time when expanding or contracting the temporal scale of the linear graphs.

6. The method of claim 1 wherein said parameters include at least one parameter pertaining to poles of the large rotary electric machine.

7. The method of claim 1 wherein said parameters include at least one parameter pertaining to end windings of the large rotary electric machines.

8. The method of claim 1 further comprising displaying human-readable identifiers of corresponding ones of the parameters adjacent corresponding ones of the graphs.

9. The method of claim 1 further comprising displaying a human-readable annotation indicative of said varying values of time.

10. The method of claim 1 further comprising displaying a panel with human-readable information pertaining to the nature of the large rotary electric machine.

11. A dashboard presenting data pertaining to a plurality of parameters, the dashboard comprising a plurality of graphs, each graph representing a sequence of severity levels of a corresponding one of the parameters along a linear axis corresponding to varying values of said time, with different ones of the severity levels corresponding to different ranges of deviation of amplitude values of the corresponding parameter from normal operating conditions and different ones of the severity levels encoded as different colors or tones, the graphs disposed parallel to one another.

12. The dashboard of claim 11 wherein said different severity levels correspond to increasing deviations from a range of said amplitude values corresponding to a normal severity level, and include at least one higher severity level, further comprising a warning icon associated to a higher severity level displayed in at least one of the linear graphs.

13. The dashboard of claim 11 wherein said parameters include at least one parameter pertaining to poles of the large rotary electric machine.

14. The dashboard of claim 11 wherein said parameters include at least one parameter pertaining to end windings of the large rotary electric machines.

15. The dashboard of claim 11 further comprising human-readable identifiers of corresponding ones of the parameters adjacent corresponding ones of the graphs.

16. The dashboard of claim 11 further comprising a human-readable annotation indicative of said varying values of time.

17. The dashboard of claim 11 further comprising a panel with human-readable information pertaining to the nature of the large rotary electric machine.

18. A method of displaying data pertaining to a plurality of parameters of a rotary machine on a display screen using a computer, the method comprising: displaying a plurality of graphs disposed parallel to one another, each graph extending linearly from a first end to a second end along a temporal axis spanning incremental values of time, and representing a sequence of severity levels of a corresponding one of the parameters encoded as different colors or tones over the incremental values of time, the incremental values of time being common to each one of the plurality of graphs such that severity levels aligned transversally to the temporal axes correspond to simultaneous moments in time.
